(19) United States
(12) Patent Application Publication
(10) Pub. No.: US 2026/0010699 A1
(43) Pub. Date: Jan. 8, 2026

(54) POWER MANAGEMENT CLUSTER DESIGN SYSTEM AND METHOD USING A NO-CODE APPROACH

(71) Applicant: ITDA SEMICONDUCTOR CO., LTD., Hwaseong-si (KR)

(72) Inventors: Ingyu KIM, Hwaseong-si (KR); Hoyeon JEON, Seongnam-si (KR); Ahchan KIM, Hwaseong-si (KR)

(73) Assignee: ITDA SEMICONDUCTOR CO., LTD., Hwaseong-si (KR)

(21) Appl. No.: 19/255,768

(22) Filed: Jun. 30, 2025

(30) Foreign Application Priority Data
Jul. 2, 2024 (KR) 10-2024-0086592
Mar. 10, 2025 (KR) 10-2025-0030378

(51) Int. Cl. G06F 30/34

(52) U.S. Cl. CPC G06F 30/34

(57) ABSTRACT

The present disclosure provides a system and method for designing a power management cluster using a no-code approach, enabling test reset delivery through the same path as a functional reset in test mode. The system includes at least one processor executing instructions stored in memory, the instructions comprising: generating a power instance from power component information; generating a reset controller instance upstream of the power instance to transmit a reset output to a target; setting first connection information between the target and the reset controller instance; generating a reset test controller instance including a test mode TDR block and a test control TDR block; setting second connection information between the reset and reset test controller instances; and generating hardware code based on the components and connection information.

### STATEMENT REGARDING GOVERNMENT SPONSORED RESEARCH OR DEVELOPMENT

This invention was made with support from the Ministry of SMEs and Startups through a grant funded by the Korea Technology and Information Promotion Agency for SMEs (TIPA), under Project Unique Number 1425182152 and Project Number RS-2023-00302523, within the Startup Growth Technology Development (R&D) program. The project titled “Low-Code Based Low-Power Semiconductor Solution” was executed by ITDA Semiconductor Co., Ltd., with the research period spanning from Jul. 1, 2023, to Jun. 30, 2026. However, no rights in the invention are held by the government of the Republic of Korea.

### CROSS-REFERENCE TO RELATED APPLICATION

This application claims the benefit of and priority to Korean Patent Application Nos. 10-2024-0086592, filed on Jul. 2, 2024, and 10-2025-0030378, filed on Mar. 10, 2025, the entire disclosures of which are incorporated herein by reference in their entirety.

### TECHNICAL FIELD

The present disclosure relates to a system and method for designing a power management cluster of a system-on-chip, and more specifically, to a system and method for designing a power management cluster using a no-code approach so that a test reset is delivered through the same path as a functional reset path in a test mode.

### BACKGROUND

A system-on-chip (SoC) refers to a technology that integrates various functional blocks such as a central processing unit (CPU), a memory, an interface, a digital signal processing circuit, and an analog signal processing circuit into a single semiconductor integrated circuit to implement a computer system or other electronic system, or an integrated circuit (IC) integrated according to the technology. The SoC has evolved into more complex systems including various functional blocks such as processors, multimedia, graphics, interfaces, and security.

The SoC may be driven in a test mode to detect defects during the design and manufacturing process and to verify that the SoC operates properly, and may be driven in a functional mode when passing a test and operating normally.

In general, power and clock design are important for the SoC. The power and clock design process of the SoC may be configured of a power/clock diagram drawing stage, a Verilog coding and scripting stage, a primary documentation stage, a unified power format/standard design constraint (UPF/SDC) file generation stage, an implementation layout design stage, a secondary documentation stage, a design for testability (DFT) controller insertion stage, a hardware system analysis stage, and a software optimization stage.

The power/clock diagram drawing stage visually represents the power and clock structure and draws a block diagram to represent the power domain and clock tree. The power/clock diagram drawing stage merely represents the clock elements and their link relationships in a diagram. The Verilog coding and scripting stage performs the register transfer level (RTL) design of the hardware by writing Verilog code and scripts used to define and implement the functions of the SoC. In other words, developers manually generate an RTL code based on the power/clock diagram drawing results.

The primary documentation stage is configured to document the design intent and structure at the beginning of a project and to write various types of documents such as requirements specifications, architecture design, and power/clock diagrams required by a plurality of interested parties such as a verification team and software development team.

The UPF/SDC file generation stage is configured to generate the UPF and SDC files to control power management and timing constraints and to generate inputs required for hardware synthesis.

The implementation layout design stage is configured to design and perform placement of the actual SoC chip layout at the gate level. The secondary documentation stage is configured to update and supplement various documents to reflect changes in the design and implementation. The DFT controller insertion stage is configured to design and integrate the DFT controller and logic circuits into the SoC for testing and debugging. The hardware system analysis stage is configured to check and analyze the operation of the hardware through simulation and verification to check the accuracy and efficiency of the design, and the software optimization stage is configured to optimize the software performance by profiling and optimizing the software code running on the SoC.

In general, in a power/clock diagram drawing stage, the path of the functional clock/data/reset operating in the functional mode is designed, and in a DFT controller insertion stage, the path of the test clock/reset operating in the test mode is designed. In other words, the functional clock/reset design stage and the test clock/reset design stage were separated and performed separately. As a result, a power management unit is designed so that when driven in a functional mode, a functional reset signal is provided to an IP block through a functional reset path, and when driven in a test mode, a test reset signal is delivered to the IP block through a path different from the functional reset path.

The power management unit designed as such may not test whether power elements are operating normally because the power elements of the power management unit are not driven in a reset test mode of the SoC. In addition, since the functional reset path and the test reset path are different from each other, tests are not performed for all the functional reset paths, which reduces test coverage.

### SUMMARY

An aspect of the present disclosure is directed to providing a system and method for designing a power management cluster using a no-code approach, which enables a test reset to be delivered through the same path as a functional reset path in a test mode, and enables testing whether a reset function operates properly for each power element and IP block configuring a system-on-chip during a reset test.

An embodiment of the present disclosure may be implemented in various ways, including a device (system), a method, a computer program stored in a computer-readable medium, or a computer-readable medium having a computer program stored therein.

A power management cluster design system using a no-code approach according to an embodiment of the present disclosure includes: a memory configured to store at least one instruction; a power component storage in which power component information, reset controller component information, and reset test controller component information configuring a power management cluster are stored; a hardware code logic storage in which hardware code logic for generating the designed power management cluster as hardware code is stored; and at least one processor configured to execute the at least one instruction stored in the memory. The at least one instruction includes instructions for: generating a power instance based on power component information; generating a reset controller instance that is disposed upstream of the power instance and transmits a reset output to a target including the power instance; setting first connection information between the target and the reset controller instance; generating a reset test controller instance that includes a test mode TDR block and a test control TDR block corresponding to the reset controller instance; setting second connection information between the reset controller instance and the reset test controller instance; and generating the hardware code based on the power instance, the reset controller instance, the first connection information, the reset test controller instance, the second connection information, and the hardware code logic.

Preferably, the reset controller instance is one of a leading reset controller instance or a following reset controller instance.

More preferably, the leading reset controller instance includes: a synchronizer block connected to a functional clock of the target; a first test multiplexer block having two input terminals respectively connected to a scan reset control signal (ltest_reset) and a reset input (RESET_IN), and having a selection terminal connected to a scan test enable signal (ltest_en); a first OR operator block having two input terminals respectively connected to an output of the first test multiplexer block and a scan reset deactivation signal (ltest_rstdisable), and having an output terminal connected to the synchronizer block; a second OR operator block having two input terminals respectively connected to an output of the synchronizer block and the scan reset deactivation signal (ltest_rstdisable); and a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

More preferably, the following reset controller instance includes: a synchronizer block connected to a functional clock of the target; a first test multiplexer block in which a selection terminal and one input terminal are fixed to a zero level, and a reset input is connected to another input terminal; a first OR operator block having two input terminals respectively connected to an output of the first test multiplexer block and a scan reset deactivation signal (ltest_rstdisable), and having an output terminal connected to the synchronizer block; a second OR operator block having two input terminals respectively connected to an output of the synchronizer block and the scan reset deactivation signal (ltest_rstdisable); and a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

Preferably, the reset test controller instance is implemented based on a built-in IEEE1687 standard.

Preferably, the test mode TDR block is set to output a reset test mode signal (TEST_MODE) to the reset controller instance to activate or deactivate the test mode of the target, and the test control TDR block is set to output reset test data (TEST_MODE_RESET) to the reset controller instance in the test mode of the target.

More preferably, the test control TDR block comprises a plurality of flip-flop blocks corresponding to the number of bits of the reset test data.

Preferably, the test mode TDR block and the test control TDR block are each set via an internal joint test action group (IJTAG) interface.

Preferably, the power component is at least one of a reset component, a clock link component, a cold reset control component, a soft reset control component or a domain power manager (PMD) connection component.

A power management cluster design method using a no-code approach according to an embodiment of the present disclosure is performed by at least one processor in a computer system including: a power component storage in which power component information, reset controller component information, and reset test controller component information configuring a power management cluster are stored; and a hardware code logic storage in which hardware code logic for generating the designed power management cluster as hardware code is stored. The method includes: generating a power instance based on power component information; generating a reset controller instance that is disposed upstream of the power instance and transmits a reset output to a target including the power instance; setting first connection information between the target and the reset controller instance; generating a reset test controller instance that includes a test mode TDR block and a test control TDR block corresponding to the reset controller instance; setting second connection information between the reset controller instance and the reset test controller instance; and generating the hardware code based on the power instance, the reset controller instance, the first connection information, the reset test controller instance, the second connection information, and the hardware code logic.

Preferably, the reset controller instance is one of a leading reset controller instance or a following reset controller instance.

More preferably, the leading reset controller instance includes: a synchronizer block connected to a functional clock of the target; a first test multiplexer block having two input terminals respectively connected to a scan reset control signal (ltest_reset) and a reset input (RESET_IN), and having a selection terminal connected to a scan test enable signal (ltest_en); a first OR operator block having two input terminals respectively connected to an output of the first test multiplexer block and a scan reset deactivation signal (ltest_rstdisable), and having an output terminal connected to the synchronizer block; a second OR operator block having two input terminals respectively connected to an output of the synchronizer block and the scan reset deactivation signal (ltest_rstdisable); and a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

More preferably, the following reset controller instance includes: a synchronizer block connected to a functional clock of the target; a first test multiplexer block in which a selection terminal and one input terminal are fixed to a zero level, and a reset input is connected to another input terminal; a first OR operator block having two input terminals respectively connected to an output of the first test multiplexer block and a scan reset deactivation signal (ltest_rstdisable), and having an output terminal connected to the synchronizer block; a second OR operator block having two input terminals respectively connected to an output of the synchronizer block and the scan reset deactivation signal (ltest_rstdisable); and a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

Preferably, the reset test controller instance is implemented based on a built-in IEEE1687 standard.

Preferably, the test mode TDR block is set to output a reset test mode signal (TEST_MODE) to the reset controller instance to activate or deactivate the test mode of the target, and the test control TDR block is set to output reset test data (TEST_MODE_RESET) to the reset controller instance in the test mode of the target.

More preferably, the test control TDR block comprises a plurality of flip-flop blocks corresponding to the number of bits of the reset test data.

Preferably, the test mode TDR block and the test control TDR block are each set via an internal joint test action group (IJTAG) interface.

Preferably, the power component is at least one of a reset component, a clock link component, a cold reset control component, a soft reset control component or a domain power manager (PMD) connection component.

A computer program stored in a computer-readable storage medium is provided to execute the aforementioned method according to an embodiment of the present disclosure on a computer.

### ADVANTAGEOUS EFFECTS

An embodiment of the present disclosure provides the following benefits.

According to an embodiment of the present disclosure, when a functional reset path operating in a functional mode is designed in a power/clock diagram drawing stage, a test reset path operating in a test mode can be automatically designed at the same time.

According to an embodiment of the present disclosure, since a separate DFT controller insertion stage can be omitted, resources required for designing a power management cluster can be reduced, and the efficiency of design work can be effectively improved.

According to an embodiment of the present disclosure, a power management cluster can be designed using a no-code approach so that an operator can test a reset path of a power element in a test mode without coding knowledge or clock process knowledge.

The power management cluster designed according to an embodiment of the present disclosure can test whether the elements configuring the functional reset path operate normally because the test reset path is formed in the same path as the functional reset path, thereby expanding the test coverage of the power management cluster.

The power management cluster designed according to an embodiment of the present disclosure can expand the test coverage by allowing a reset test to be performed on a synchronizer located on the functional reset path.

When the system-on-chip designed according to an embodiment of the present disclosure is driven in a test mode, a test reset can be provided to the IP block and each element, so that the reset test for each element and IP block of the system-on-chip can be smoothly performed.

The benefits of the present disclosure are not limited to those mentioned above, and other benefits not mentioned herein will be clearly understood by those having ordinary skill in the technical field to which the present disclosure pertains (hereinafter, “those skilled in the art”) from the following description.

### BRIEF DESCRIPTION OF THE DRAWINGS

Embodiments of the present disclosure will be described with reference to the accompanying drawings described below, where similar reference numerals indicate similar elements, but embodiments are not limited.

FIG. 1 is a block diagram illustrating a typical system-on-chip (SoC).

FIG. 2 is a detailed configuration diagram illustrating a power management cluster (PMC) included in the system-on-chip of FIG. 1.

FIG. 3 is an embodiment of a reset domain including a root power manager and a domain power manager designed according to an embodiment of the present disclosure.

FIG. 4 is another embodiment of a reset domain including a root power manager and a domain power manager designed according to an embodiment of the present disclosure.

FIG. 5 is an embodiment of a reset domain including a second power management interface and an IP block designed according to an embodiment of the present disclosure.

FIG. 6 is a detailed diagram illustrating a leading reset controller of FIGS. 3 to 5.

FIG. 7 is a detailed diagram illustrating a following reset controller of FIG. 4.

FIG. 8 is a configuration diagram illustrating a power management cluster design system using a no-code approach according to an embodiment of the present disclosure.

FIG. 9 is a diagram illustrating an example of a display screen of a power management cluster design system using a no-code approach according to an embodiment of the present disclosure.

FIG. 10 is an operation flow diagram illustrating a power management cluster design method using a no-code approach according to an embodiment of the present disclosure.

FIG. 11 illustrates an exemplary computing device for performing the method and/or embodiments described above.

### DETAILED DESCRIPTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding components are assigned the same reference numerals. Further, in the following description of the embodiments, duplicate descriptions of the same or corresponding components may be omitted. However, even if descriptions of components are omitted, it is not intended that such components are not included in any embodiment.

The advantages and features of the embodiments of the present disclosure and methods of achieving the same will be apparent from the embodiments described below in connection with the accompanying drawings. However, the present disclosure is not limited to the disclosed embodiments disclosed below, and may be implemented in various different forms, and the present embodiments are merely provided to fully disclose the scope of embodiments to those skilled in the art to which the present disclosure pertains.

The terms used herein will be briefly described prior to describing the disclosed embodiments in detail. The terms used herein have been selected as general terms which are widely used at present in consideration of the functions of the present disclosure, and this may be altered according to the intent of a person skilled in the art, conventional practice, or introduction of new technology. Further, in a specific case, a term is arbitrarily selected by the applicant, and the meaning of the term will be described in detail in a corresponding description of the embodiments. Accordingly, the terms used in the present disclosure should be defined based on the meaning of the terms and the overall content of the present disclosure rather than a simple name of each of the terms.

As used herein, the singular forms are intended to include the plural forms as well, unless the context clearly indicates the singular forms. Further, the plural forms are intended to include the singular forms as well, unless the context clearly indicates the plural forms. Further, throughout the description, when a portion is stated as including a component, it intends to mean that the portion may additionally include another component, rather than excluding the same, unless specified to the contrary.

In this present disclosure, the terms “comprising,” “having,” or the like are used to specify that features, steps, operations, elements and/or components exist, and they do not preclude the addition of one or more other features, steps, operations, elements, components, and/or combinations thereof.

In the present disclosure, when a particular component is referred to as being “coupled to,” “combined with,” “connected to,” “related to,” or as “responding to” any other component, the particular component may be directly coupled to, combined with, connected to, and/or related to, or may directly respond to the other component; however, the present disclosure is not limited to the relationship. For example, there may be one or more intermediate components between a particular component and another component. In addition, in the present disclosure, “and/or” may include one or more of the listed items or a combination of at least a portion of one or more of the listed items.

In the present disclosure, the terms such as “first” and “second” are used to distinguish a particular component from the other components, and thus the component should not be limited by those terms. For example, a “first” component may be used to indicate a component in a form similar to or the same as a “second” component.

In an embodiment of the present disclosure, the term “power component” may refer to tools utilized in designing a power manager, in other words, a domain power manager and a root power manager. The power component utilized in designing the domain power manager includes a reset component and a clock link component. The power component utilized in designing the root power manager includes a cold reset control component, a soft reset control component, and a domain power manager (PMD) connection component.

In an embodiment of the present disclosure, the term “power instance” is a power component included in a power manager, and may be a power component added to a design window by the manipulation of a user. The power instance may be automatically added by the design system of an embodiment of the present disclosure. The characteristics of the relevant power manager may be determined by the power instances included in each power manager. For some power components, when a user drags and drops a power component icon of a power component window to a design window area, a power instance corresponding to the relevant power component may be generated. When the power instance is generated, a register corresponding to the relevant power instance may be automatically generated. For some power components, when a new root power manager is generated, it may be automatically added, and the relevant power instance and the register corresponding thereto may be automatically generated.

The domain power manager and the root power manager may include a plurality of power instances for each type of power component. As a power component for designing the domain power manager, a power instance generated based on the reset component is referred to as a reset instance, and a power instance generated based on the clock link component is referred to as a clock link instance. As a power component for designing the root power manager, a power instance generated based on the domain power manager connection component is referred to as a domain power manager connection instance, a power instance generated based on the cold reset control component is referred to as a cold reset control instance, and a power instance generated based on the soft reset control component is referred to as a soft reset control instance. In addition, each power instance may be generated based on each power component. When a power instance is generated, a register field value assigned to the relevant power instance may be automatically assigned. In addition, hardware code may be generated based on the register field value of the power instance.

In an embodiment of the present disclosure, a power element is a hardware-coded module based on a designed power instance, which may configure a power management cluster.

To sum up, the power component is a material for designing the power management cluster, the power instance is a node included when designing the power management cluster, and the power element is a module that is implemented as hardware code based on the designed power instance and may operate in the power management cluster.

In an embodiment of the present disclosure, a target may be a destination of a reset signal. The target may be at least one of IP blocks, power elements configuring a power management unit, clock elements configuring a clock management unit, or internal logic circuits of each unit. The clock management unit provides a functional clock to the target. A reset controller may be configured at the upstream of each target to control the reset of the target.

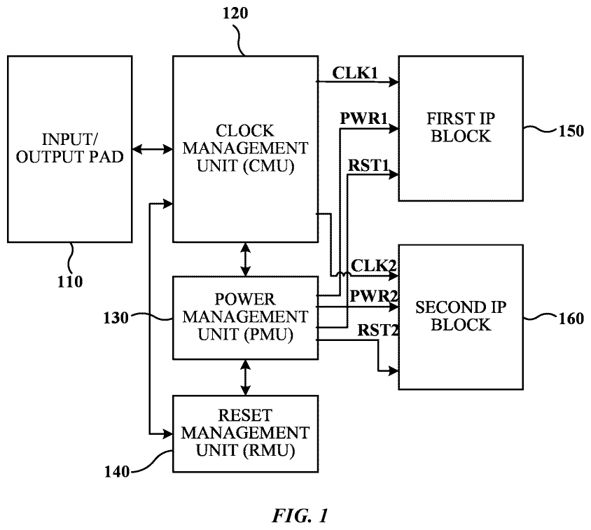

FIG. 1 is a block diagram illustrating a typical system-on-chip (SoC).

The SoC may include an input/output pad 110, a clock management unit (CMU) 120, a power management unit (PMU) 130, a reset management unit (RMU) 140, and one or more intellectual property (IP) blocks 150, 160. When the SoC operates in a functional mode, the CMU 120 may generate first and second functional clocks (CLK1, CLK2) to be provided to each of the first and second IP blocks 150, 160.

Each of the first and second IP blocks 150, 160 is connected to a system bus and may communicate with each other through the system bus. Each of the first and second IP blocks 150, 160 may be a processor, a graphic processor, a memory controller, and an input and output interface block.

The CMU 120 includes a plurality of clock elements, wherein a first functional clock (CLK1) is provided to the first IP block 150 when the first IP block 150 operates, and a second functional clock (CLK2) is provided to the second IP block 160 when the second IP block 160 operates.

The PMU 130 includes a plurality of power elements and controls power supplied to the SoC. For example, when the SoC enters a standby mode, the PMU 130 provides a power sequence (PWR1, PWR2) for powering down the first and second IP blocks 150, 160 so that power supplied to the IP blocks is cut off. In addition, when the SoC operates in a driving mode, the PMU 130 provides a power sequence (PWR1, PWR2) for powering up the first and second IP blocks 150, 160 so that power is supplied to each IP block.

The RMU 140 detects a reset mode of the SoC and transmits a reset signal (RST1, RST2) to the first and second IP blocks 150, 160 through the PMU 130 so that the hardware is initialized. In addition, the reset signal generated from the RMU 140 is also transmitted to the PMU 130 and the CMU 120, so that when the IP block 150, 160 is reset, the power elements of the PMU 130 and the clock elements of the CMU 120 are also reset.

The reset mode may be used to initialize a specific portion of the system or to return the system to a specific state. The reset mode may include a power on reset (POR_reset), a pin activated reset (PAD_reset), a software reset, a watchdog reset, a brown out reset (BOR_reset), a cold reset, and a soft reset.

The cold reset is a reset that occurs when the power is turned off and then turned on again, and all system states may be initialized. The power on reset and the pin-activated reset may be cold resets. The soft reset is a reset that occurs while the power is on, and only a portion of the system is partially initialized. Only the CPU and some hardware modules are reset, while the memory and other components may be maintained.

In other words, depending on various types of reset, all elements and IP blocks of the SoC device may be reset, or only some IP blocks or some elements may be reset.

While the SoC device operates in a functional mode, it is necessary to initialize elements or IP blocks configuring the SoC device in order to maintain the reliability, stability, and security of the system, such as rebooting the system, recovering from system errors, updating firmware/software, responding to power supply instability, solving clock and timing issues, and responding to external condition changes.

The RMU 140 may include a functional reset generation unit that generates and distributes a reset signal in a functional mode. The functional reset generation unit may receive a trigger from various reset sources (power-on, external reset pin, watchdog timer, and software command) and generate a reset signal to distribute to elements within the SoC device so that the corresponding elements are reset. The path along which the reset signal is transmitted when the system-on-chip operates in a functional mode is referred to as a functional reset path, and the destination of the reset signal may be referred to as the target.

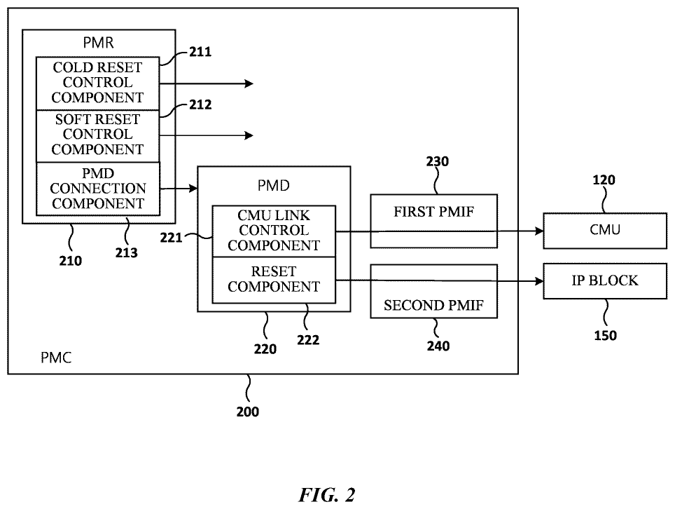

FIG. 2 is a detailed configuration diagram illustrating a power management cluster (PMC) included in the system-on-chip of FIG. 1.

The system-on-chip includes a power management cluster (PMC) 200. The PMC 200 is connected to at least one IP block 150. The system-on-chip may include at least one PMC 200. The IP block 150 may be the first IP block 150 of FIG. 1.

The PMC 200 may include a domain power manager (PMD; Power Management for Domain) 220 that controls power of the IP block 150, a root power manager (PMR; Power Management for Root) 210 that manages the PMD 220, a first power management interface (PMIF) 230 disposed between the PMD 220 and the CMU 120, and a second PMIF 240 disposed between the PMD 220 and the IP block 150. The CMU 120 may provide a functional clock to the PMR 210, the PMD 220, the first and second PMIFs 230, 240, and the IP block 150. The CMU 120 may be the CMU 120 of FIG. 1.

The PMR 210 and the PMD 220 are disposed in an always-on (AON) domain area, the first power management interface 230 is disposed on the side of the CMU 120, and the second power management interface 240 is disposed on the side of the IP block 150.

The PMR 210 may include a cold reset control element 211 that receives a cold reset signal and controls all clock/power elements and all IP blocks of the system-on-chip device to be reset, a soft reset control element 212 that receives a soft reset signal and controls some elements and some IP blocks of the system-on-chip device to be reset, and a PMD connection element 213 that manages a connection with the PMD. The PMD 220 may be connected to the PMR 210 via the PMD connection element 213. In the drawing, one PMD 220 is connected to the PMR 210, but a plurality of PMDs may be connected to one PMD connection element, and a plurality of PMDs may be connected via a plurality of PMD connection elements.

The cold reset signal and the soft reset signal may be provided from a functional reset generation unit. The cold reset control element 211 and the soft reset control element 212 may control a register of the PMR 210 and/or a register of the PMD 220 so that logic circuits and clock/power elements controlled by the registers are reset. In addition, the internal logic circuit controlled by the PMR 210 may be further reset.

The PMD 220 includes a CMU link control element 221 for controlling a link with the CMU 120, and a reset element 222 for transmitting a reset signal to the IP block 150. In addition, the PMD 220 further includes a PMD internal logic circuit, which is a logic circuit within the PMD itself.

The first and second power management interfaces 230 and 240 each include a PMIF internal logic circuit and physically transmit the control signal output from the PMD 220 to the clock control unit 120 and the IP block 150.

As described above, the PMR 210 and the PMD 220 are physically disposed in the same AON domain area, the first power management interface 230 and the CMU 120 are physically disposed in the same power domain area, and the second power management interface 240 and the IP block 150 are physically disposed in the same power domain area.

In the present disclosure, the reset domain may be divided based on the physical power domain area. In other words, the PMR 210 and the PMD 220 may configure one reset domain, the first power management interface 230 and the CMU 120 may configure one reset domain, and the second power management interface 240 and the IP block 150 may configure one reset domain.

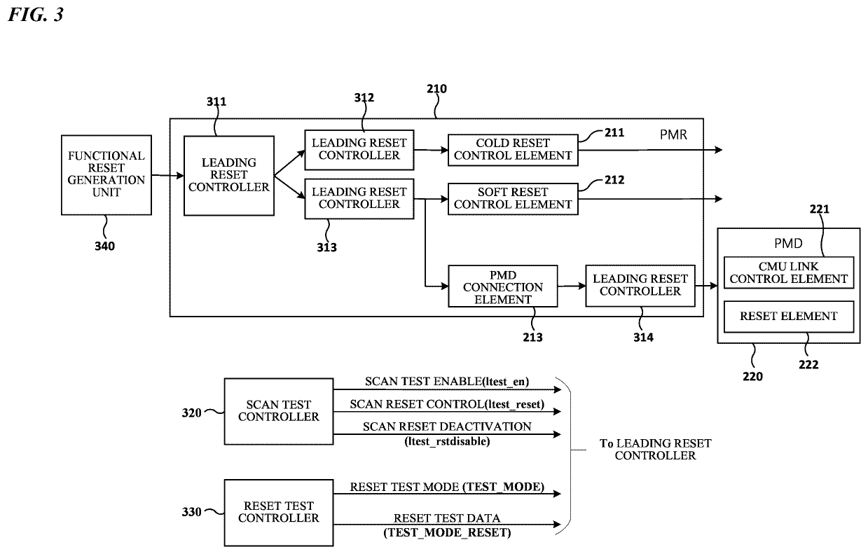

FIG. 3 is an embodiment of a reset domain including a root power manager and a domain power manager designed according to an embodiment of the present disclosure.

The reset domain may include a plurality of reset controllers 311, 312, 313, and 314 disposed upstream of a target, which receive a functional reset and a functional clock of the target and selectively output a functional reset or a test reset synchronized with the functional clock. These reset controllers may be disposed in the functional reset path of the target. The functional reset path of any target may include at least one reset controller. All of the plurality of reset controllers 311, 312, 313, and 314 may be leading reset controllers.

The target may include elements 211, 212, 213 that configure the PMR 210, a PMR internal logic circuit, elements 221, 222 that configure the PMD 220, and a PMD internal logic circuit.

The leading reset controller 312 may have the cold reset control element 211 as a target, and may selectively output a functional reset or a test reset synchronized with the functional clock of the cold reset control element 211 to the cold reset control element 211. The leading reset controller 313 may have the soft reset control element 212, the PMR internal logic circuit and the PMD connection element 213 as targets, and may selectively output the functional reset or the test reset synchronized with the functional clock of the target to the respective targets. The leading reset controller 314 may have the PMD 220 as a target, and may selectively output the functional reset or the test reset synchronized with the functional clock of the PMD to the PMD 220.

When a register is set by the functional reset generation unit 340, the functional reset may be input to the leading reset controller 311. The reset output of the leading reset controller 311 is then provided as the reset input to the downstream leading reset controllers 312 and 313. The reset output of the leading reset controller 312 is provided to the cold reset control element 211. The reset output of the leading reset controller 313 is provided to the soft reset control element 212 and the PMD connection element 213, and also serves as the reset input to the leading reset controller 314. The reset output of the leading reset controller 314 is provided to the PMD 220.

The reset domain includes: a scan test controller 320 configured to output a scan test enable signal (ltest_en) indicating whether a scan test mode is activated, a scan reset control signal (ltest_reset) for controlling reset in the scan test mode, and a scan reset deactivation signal (ltest_rstdisable) for deactivating reset in the scan test mode, to the leading reset controllers 311 to 314; and a reset test controller 330 configured to output a reset test mode signal (TEST_MODE) indicating whether the target is in a test mode and target reset test data (TEST_MODE_RESET) to each of the leading reset controllers 311 to 314.

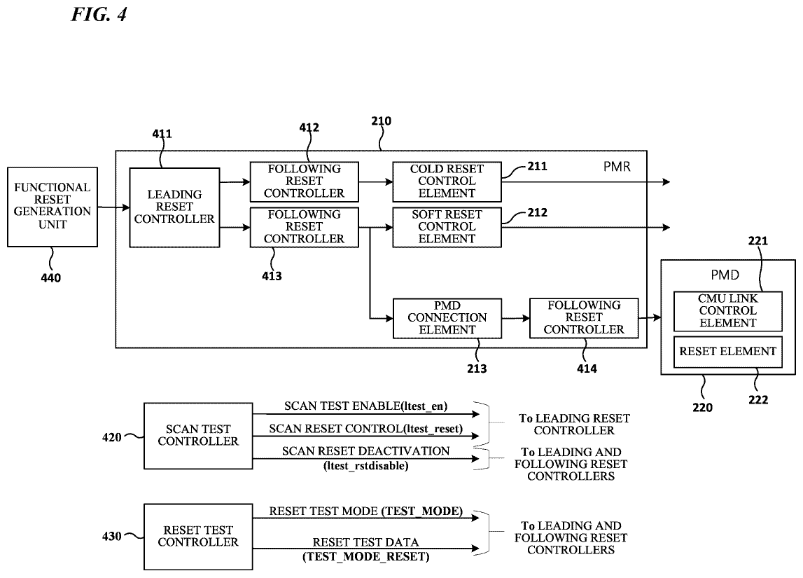

FIG. 4 is another embodiment of a reset domain including a root power manager and a domain power manager designed according to an embodiment of the present disclosure.

The reset domain includes a plurality of reset controllers 411, 412, 413, 414 disposed upstream of a target, which receive a functional reset and a functional clock of the target and selectively output the functional reset or test reset synchronized with the functional clock. These reset controllers may be disposed in a functional reset path of the target. The functional reset path of any target may include at least one reset controller. The plurality of reset controllers includes a leading reset controller 411 disposed at the most upstream end of a functional reset path within the reset domain, and following reset controllers 412, 413, and 414 connected downstream of the leading reset controller 411 within the reset domain.

The target may include the elements 211, 212, 213 that configure the PMR 210, the PMR internal logic circuit, the elements 221, 222 that configure the PMD 220, and the PMD internal logic circuit.

When a functional reset generation unit 440 sets a register, the functional reset may be input to the leading reset controller 411, and a reset output of the leading reset controller 411 may be provided as a reset input to the following reset controllers 412 and 413 downstream thereof.

The following reset controller 412 has the cold reset control element 211 as a target and may selectively output a functional reset or test reset synchronized with the functional clock of the cold reset control element 211 to the cold reset control element 211. The following reset controller 413 has the soft reset control element 212, the PMR internal logic circuit and the PMD connection element 213 as targets and may selectively output a functional reset or test reset synchronized with the functional clock of the target to each target. The following reset controller 414 has the PMD 220 as a target and may selectively output a functional reset or test reset synchronized with the functional clock of the PMD to the PMD 220.

The reset output of the leading reset controller 411 is provided as a reset input to the downstream following reset controllers 412 and 413. The reset output of the following reset controller 412 is provided to the cold reset control element 211. The reset output of the following reset controller 413 is provided to the soft reset control element 212 and the PMD connection element 213, and is also provided as a reset input to the downstream following reset controller 414. The reset output of the following reset controller 414 is provided to the domain power manager 220.

The reset domain includes: a scan test controller 420 that outputs a scan test enable signal (ltest_en) indicating whether a scan test mode is activated, a scan reset control signal (ltest_reset) controlling reset in the scan test mode, and a scan reset deactivation signal (ltest_rstdisable) controlling the reset to be deactivated in the scan test mode; and a reset test controller 430 that outputs the reset test mode signal (TEST_MODE) indicating whether a target is in a test mode and target reset test data (TEST_MODE_RESET).

The scan test enable signal (ltest_en) and the scan reset control signal (ltest_reset) are provided only to the leading reset controller 411. The scan reset deactivation signal (ltest_rstdisable), the reset test mode signal (TEST_MODE), and the reset test data (TEST_MODE_RESET) are provided to both the leading reset controller 411 and the following reset controllers 412, 413, 414.

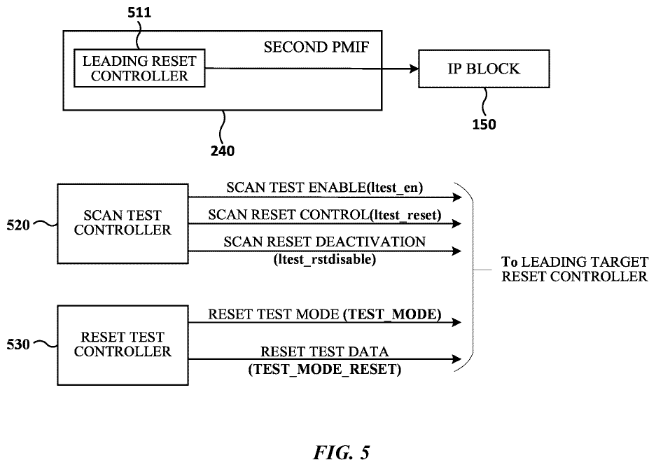

FIG. 5 is an embodiment of a reset domain including a second power management interface and an IP block designed according to an embodiment of the present disclosure.

The reset domain may include a leading reset controller 511 that is disposed upstream of the target, receives a functional reset and a functional clock of the target and selectively outputs a functional reset or test reset synchronized to the functional clock. The leading reset controller 511 is disposed at the most upstream end of a functional reset path within the reset domain. Although the reset domain of an embodiment of FIG. 5 is described as including only the leading reset controller, it is not limited thereto and the following reset controller may be additionally disposed downstream of the leading reset controller. The target may include the IP block 150 and the PMIF internal logic circuit of the second power management interface.

The reset domain further includes: a scan test controller 520 that outputs a scan test enable signal (ltest_en) indicating whether a scan test mode is activated, a scan reset control signal (ltest_reset) controlling reset in the scan test mode, and a scan reset deactivation signal (ltest_rstdisable) controlling the reset to be deactivated in the scan test mode to the leading reset controller 511; and a reset test controller 530 that outputs a target reset test mode signal (TEST_MODE) indicating whether the target is in a test mode and the target reset test data (TEST_MODE_RESET) to the leading reset controller 511.

The scan test controller 320 of FIG. 3, the scan test controller 420 of FIG. 4, and the scan test controller 520 of FIG. 5 may be the same component. The reset test controller 330 of FIG. 3, the reset test controller 430 of FIG. 4, and the reset test controller 530 of FIG. 5 perform the same function, but it is preferable that a separate reset test controller 330, 430, 530 be disposed for each reset domain.

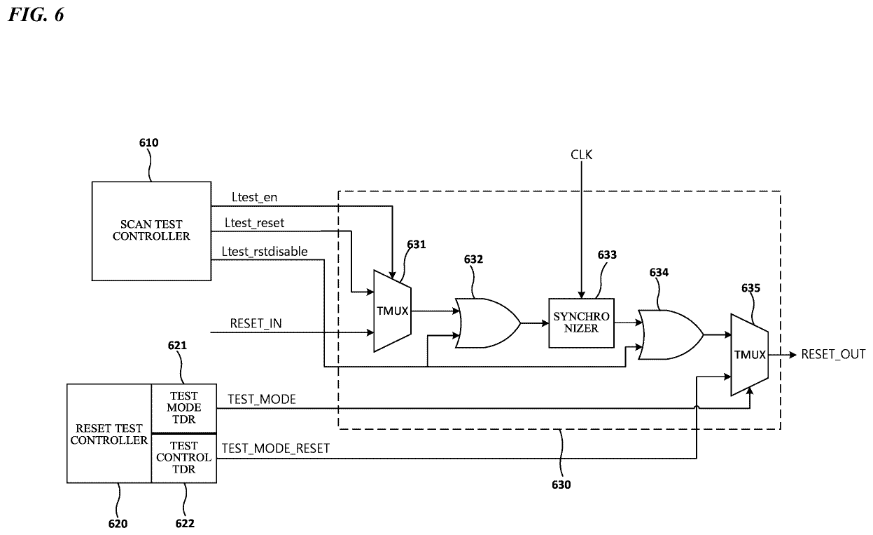

FIG. 6 is a detailed diagram illustrating a leading reset controller of FIGS. 3 to 5.

A scan test controller 610 outputs a scan test enable signal (ltest_en) indicating whether a scan test mode is activated, a scan reset control signal (ltest_reset) controlling reset in the scan test mode, and a scan reset deactivation signal (ltest_rstdisable) controlling the reset to be deactivated in the scan test mode. A reset test controller 620 outputs the reset test mode signal (TEST_MODE) indicating whether the target is in the test mode, and the reset test data (TEST_MODE_RESET).

The leading reset controller 630 is configured to activate a reset function in the scan test mode based on the scan test enable signal (ltest_en), the scan reset control signal (ltest_reset), the scan reset deactivation signal (ltest_rstdisable), the reset test mode signal (TEST_MODE), the reset test data (TEST_MODE_RESET), and the reset input (RESET_IN), and to output the reset test data to the target while the reset test mode of the target is activated.

The leading reset controller 630 includes a synchronizer 633 that synchronizes the functional reset to the functional clock of the target, and causes the synchronizer 633 to be reset while the reset function is activated in the scan test mode.

The reset test controller 620 may include a test mode test data register (TDR) 621 that outputs the reset test mode signal (TEST_MODE) indicating whether a reset test mode of the target is activated or deactivated, and a test control TDR 622 that outputs the reset test data (TEST_MODE_RESET) when the target is activated in the reset test mode. The test mode TDR 621 and the test control TDR 622 may each be implemented with a flip-flop-based shift register structure.

The reset test controller 620 may be a controller based on a built-in IEEE1687 standard. The reset test controller 620 may set the test mode TDR 621 and the test control TDR 622 via an internal joint test action group (IJTAG) interface.

The test mode TDR 621 may be configured with a flip-flop and may output the reset test mode signal indicating activation/deactivation of the reset test mode of the target to the leading reset controller 630. The reset test mode signal may be a 1-bit signal. The test control TDR 622 may be configured with a flip-flop and may output the reset test data (TEST_MODE_RESET) to the leading reset controller 630. The reset test data may be a value that determines whether to reset the target while the reset test mode is activated. Accordingly, the reset test data may be a 1-bit signal.

The leading reset controller 630 includes: a first test multiplexer (TMUX) 631 in which the scan reset control signal (ltest_reset) and the reset input (RESET_IN) are input to respective input terminals, and the scan test enable signal (ltest_en) is input to a selection terminal and outputs one of the scan reset control signal (ltest_reset) or the reset input (RESET_IN) according to the scan test enable signal (ltest_en); and a first OR operator 632 which performs an OR operation on an output of the first test multiplexer 631 and the scan reset deactivation signal (ltest_rstdisable) and outputs a result to the synchronizer 633. The functional reset may be input from a register as the reset input (RESET_IN).

When the scan test enable signal (ltest_en) is in a scan test activation mode, the first test multiplexer 631 selects and outputs the scan reset control signal. When the scan test enable signal (ltest_en) is not in the scan test activation mode, the first test multiplexer 631 selects and outputs the reset input (RESET_IN). The first OR operator 632 outputs ‘high’ when at least one of the output of the first test multiplexer 631 or the scan reset deactivation signal (ltest_rstdisable) is ‘high.’ Accordingly, the first test multiplexer 631 and the first OR operator 632 may reset the synchronizer 633 by controlling the scan reset control signal (ltest_reset) when the scan test is activated.

When the scan test is not activated, the reset input (RESET_IN) is input to the synchronizer 733, and the synchronizer 633 synchronizes the reset input with the functional clock (CLK) of the target and outputs the same.

The leading reset controller 630 includes: a second OR operator 634 that performs an OR operation on an output of the synchronizer 633 and the scan reset deactivation signal (ltest_rstdisable); and a second test multiplexer 635 in which an output of the second OR operator 634 and the reset test data (TEST_MODE_RESET) are input to respective input terminals, the reset test mode signal (TEST_MODE) is input to a selection terminal and outputs one of the output of the second OR operator 634 or the reset test data (TEST_MODE_RESET) as the reset output (RESET_OUT) according to the reset test mode signal (TEST_MODE).

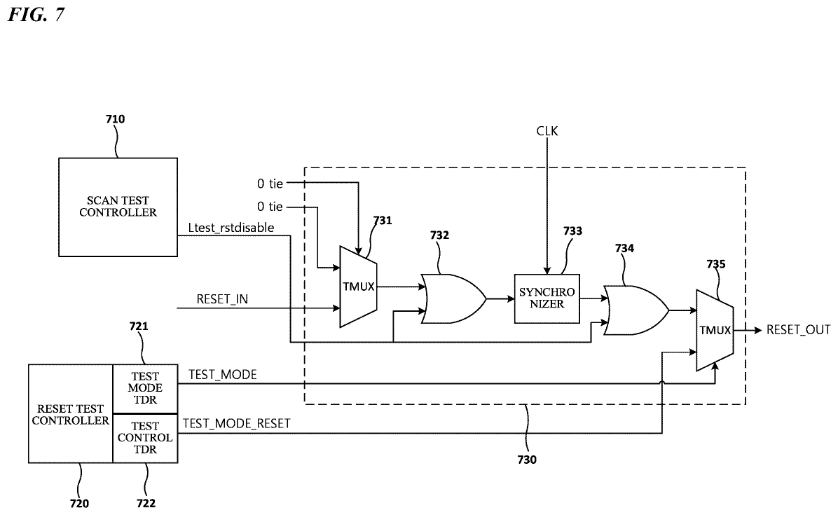

FIG. 7 is a detailed diagram illustrating a following reset controller of FIG. 4.

A scan test controller 710 outputs the scan reset deactivation signal (ltest_rstdisable) to control the reset to be deactivated in the scan test mode to a following reset controller 730.

The following reset controller 730 activates the reset function in the scan test mode based on the scan reset deactivation signal (ltest_rstdisable), the target reset test mode signal (TEST_MODE), the target reset test data (TEST_MODE_RESET), and the reset input (RESET_IN) received from an upstream reset controller, and outputs the reset test data to the target while the reset test mode is activated. In this context, the upstream reset controller may be either a leading reset controller or another following reset controller

The following reset controller 730 includes a synchronizer 733 that synchronizes the functional reset to the functional clock of the target, and causes the synchronizer 733 to be reset by the reset input (RESET_IN) while the reset function is activated in the scan test mode.

A reset test controller 720 may include a test mode test data register (TDR) 721 that outputs the reset test mode signal (TEST_MODE) indicating whether the reset test mode of the target is activated or deactivated, and a test control test data register (TDR) 722 that outputs the reset test data (TEST_MODE_RESET) when the target is activated in the reset test mode. The test mode TDR 721 and the test control TDR 722 may each be implemented with a flip-flop-based shift register structure. The reset test controller 720, the test mode TDR 721, and the test control TDR 722 of FIG. 7 perform the same functions as the reset test controller 620, the test mode TDR 621, and the test control TDR 622 of FIG. 6.

The reset test controller 720 may be a controller based on a built-in IEEE1687 standard. The reset test controller 720 may configure the test mode TDR 721 and the test control TDR 722 via an IJTAG interface.

The test mode TDR 721 may be configured with a flip-flop and may output the reset test mode signal indicating reset test mode activation/deactivation of the target to the following reset controller 730. In other words, the reset test mode signal may be a 1-bit signal. The test control TDR 722 may be configured with a flip-flop and may output the reset test data (TEST_MODE_RESET) to the following reset controller 730. The reset test data may be a value that determines whether to reset the target while the reset test mode is activated. Accordingly, the reset test data may be a 1-bit signal.

The following reset controller 730 may include: a first test multiplexer (TMUX) 731 in which a selection terminal and one input terminal are each fixed to a zero level (0 tie) and the reset input (RESET_IN) is input to another input terminal to output the reset input (RESET_IN); and a first OR operator 732 that performs an OR operation on the reset input (RESET_IN) output from the first test multiplexer 731 and the scan reset deactivation signal (ltest_rstdisable) and outputs a result to the synchronizer 733. The reset input (RESET_IN) may be input from the following reset controller or the leading reset controller upstream. The first OR operator 732 outputs ‘high’ when at least one of the reset input (RESET_IN) or the scan reset deactivation signal (ltest_rstdisable) is ‘high.’

The reset input (RESET_IN) is transmitted from the following reset controller or the leading target reset controller upstream. Accordingly, when the scan test is activated, the reset test may be performed while the reset input (RESET_IN) is transmitted along the functional reset path, and the synchronizer 733 may be reset. In addition, the synchronizer 733 outputs the reset input (RESET_IN) by synchronizing the same with the functional clock (CLK) of the target.

The following reset controller 730 includes: a second OR operator 734 configured to perform an OR operation on the output of the synchronizer 733 and the scan reset deactivation signal (ltest_rstdisable); and a second test multiplexer 735 configured to receive the output of the second OR operator 734 and the reset test data (TEST_MODE_RESET) at respective input terminals, receive the reset test mode signal (TEST_MODE) at a selection terminal, and output one of the two as the reset output (RESET_OUT) based on the reset test mode signal (TEST_MODE).

In other words, the following reset controller 730 of FIG. 7 fixes the scan test enable signal (ltest_en) and the scan reset control signal (ltest_reset) of the leading reset controller 630 of FIG. 6 to zero level so that the first test multiplexer 731 outputs the reset input (RESET_IN) to the first OR operator 732.

Thereby, the leading reset controller 630 of FIG. 6 independently and selectively outputs the scan reset control signal (ltest_reset) and the scan input (RESET_IN) based on the scan test enable signal (ltest_en). However, since the following reset controller 730 of FIG. 7 receives the scan output (RESET_OUT) from an upstream reset controller as the scan input (RESET_IN) and performs the reset, the scan reset test may be performed along the functional reset path.

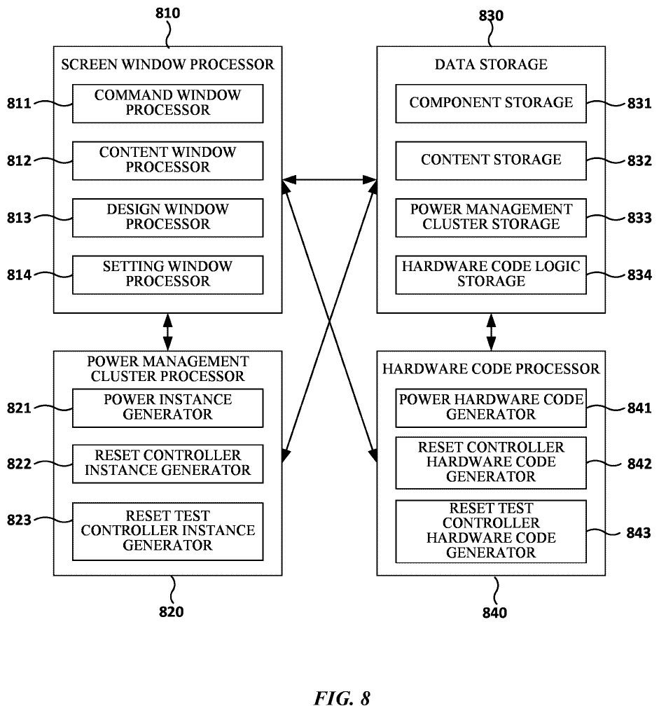

FIG. 8 is a configuration diagram illustrating a power management cluster design system using a no-code approach according to an embodiment of the present disclosure. The power management cluster design system using the no-code approach according to an embodiment of the present disclosure may be implemented as a computer system. The power management cluster design system of an embodiment of the present disclosure may be a system for designing the power management cluster of FIGS. 3 to 7.

The power management cluster design system using the no-code approach according to an embodiment of the present disclosure may include: a screen window processor 810 that detects a user input and outputs a processing result of the user input on a display screen; a power management cluster processor 820 that designs a power management cluster by generating at least one power instance based on power component information, generating a reset controller instance and a reset test controller instance, and setting a connection among the power instance, the reset controller instance, and the reset test controller instance; a data storage 830 that stores hardware code logic for generating hardware code based on the power component information and the designed power management cluster; and a hardware code processor 840 that generates hardware code corresponding to the designed power management cluster using the hardware code logic.

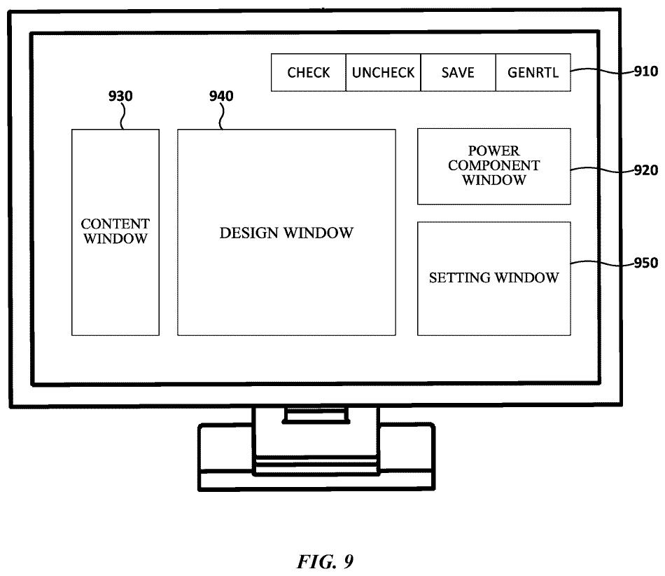

FIG. 9 is a diagram illustrating an example of a display screen of a power management cluster design system using a no-code approach according to an embodiment of the present disclosure.

The display screen of the power management cluster design system using the no-code approach according to an embodiment of the present disclosure may include: a command window 910 in which a user command is input; a power component window 920 in which power component icons are displayed; a content window 930 in which an environment for adding, deleting, and changing a list of power management clusters under design is provided and a list of power instances configuring each power management cluster under design and functional information of each power instance are hierarchically displayed; a design window 940 in which a power diagram of the power management cluster under design is displayed and an environment for adding, deleting, and changing a power instance configuring the power management cluster under design are provided; and a setting window 950 in which a functional setting environment for the power instance selected in the design window 940 is provided.

The command window 910 may include a check button for receiving an error check command in the power diagram of the power management cluster under design and the setting values of power instances that configure the power management cluster under design, an uncheck button for receiving a command to deactivate the check result, a save button for receiving a save command for the power diagram displayed in the design window 940, and a GENRTL button for receiving a hardware code generation command for the power diagram displayed in the design window 940.

The power component window 920 may display icons of a list of power components that can be used to design a power management cluster. The power components may include a cold reset control component, a soft reset control component, and a PMD connection component required for designing a root power manager. The cold reset control component and the soft reset control component are essential power components included in the root power manager and may not be displayed in the power component window 920, but may be automatically inserted into a newly generated root power manager. The power components may also include a CMU link control component and a reset component required for designing a domain power manager.

The cold reset control component, the soft reset control component, the PMD connection component, the CMU link control component, and the reset component are each implemented as hardware code and are design elements that operate as the cold reset control element 211, the soft reset control element 212, the PMD connection element 213, the CMU link control element 221, and the reset element 222 of FIGS. 2 to 4.

The content window 930 displays a list of power management clusters under design and provides an environment for adding, deleting, and changing the power management clusters under design. In addition, a list of power instances configuring each corresponding power management cluster under design may be displayed below each cluster in the list. The design window 940 displays a power diagram of the power management cluster under design and provides an environment for adding, deleting, and changing power instances configuring the power management cluster under design. When a user moves any power component from the power component window 920 to the design window 940 by a drag-and-drop operation, a power instance corresponding to the power component may be generated in the corresponding power management cluster under design.

The setting window 950 provides a functional setting environment for the power instance selected in the design window 940.

### Screen Window Processor 810

The screen window processor 810 may include: a command window processor 811 that displays buttons for receiving user commands on the command window 910 and detects input of each button of the command window 910 to cause an operation corresponding to the input button to be performed; a content window processor 812 that hierarchically displays a list of power management clusters under design and the list of power instances and register information included in each power management cluster under design on the content window 930 and detects user input on the content window 930 to cause an operation corresponding to the user input to be performed; a design window processor 813 that causes a power diagram of the power management cluster under design selected by a user to be displayed on the design window 940 and detects the user input on the design window 940 to cause an operation corresponding to the user input to be performed; and a setting window processor 814 that displays setting information of the power management cluster and power instance under design selected by a user in the setting window 950 and detects user input in the setting window 950 to perform an operation corresponding to the user input.

The command window processor 811 checks for errors in the power diagram of the power management cluster under design and the setting values of the power instances configuring the power management cluster under design when the check button is selected, and displays the portion where the error occurred. When the uncheck button is selected, the command window processor 811 restores the error portion displayed in the power diagram of the power management cluster under design to its original state and displays the same. When the save button is selected, the command window processor 811 saves the work content of the power management cluster under design displayed in the design window 940 in the data storage 830. When the GENRTL button is selected, the command window processor 811 generates hardware code for the power diagram of the power management cluster under design displayed in the design window 940.

The content window processor 812 provides an environment for adding, deleting, and changing a list of power management clusters under design and the list of power instances included in each power management cluster under design. The content window processor 812 may hierarchically display the list of power instances and the register information of each power instance down each power management cluster under design. A user may add, delete, and change the name of the power management cluster under design in the content window 930, and the list of power management clusters under design may be added, deleted, and changed in a power management cluster storage 833 in response to a user input. When a user changes the name of the power management cluster under design, the content window processor 812 may change not only the name of the power management cluster under design but also the name and register name of the power instance down the power management cluster under design all at once.

The design window processor 813 displays the power diagram of the power management cluster under design in the design window 940 and provides an environment for adding, deleting, and changing the power instance that configures the power management cluster under design. When a user performs an operation to add an arbitrary power component of the power component window 920 to the design window 940, the design window processor 813 detects the same and causes a power instance addition operation to be performed.

The setting window processor 814 causes the setting information of the power instance and power management cluster under design to be displayed and detects a user input in the setting window 950 to cause an operation corresponding to the user input to be performed.

### Data Storage 830

The data storage 830 may include: a component storage 831 that stores the power component information, reset controller component information, and reset test controller component information; a content storage 832 that stores the list of power instances included in a power management cluster under design and a register list corresponding to the power instance; the power management cluster storage 833 that stores functional information of individual power instances included in the power management cluster under design, reset controller instance information and reset test controller instance information; and a hardware code logic storage 834 that stores hardware code logic for generating hardware code based on power management cluster information under design. The reset controller instance is a design element implemented in hardware code to operate as the leading reset controller or the following reset controller of FIGS. 3 to 7, and the reset test controller instance is a design element implemented in hardware code to operate as the reset test controller of FIGS. 3 to 7.

The power components stored in the component storage 831 may include a cold reset control component, a soft reset control component, a PMD connection component, a CMU link control component, and a reset component. In addition, the component storage 831 stores a reset controller component and a reset test controller component.

The content storage 832 stores the power management cluster under design, the list of power instances, and a list of registers corresponding to the power instances.

The power management cluster storage 833 stores each piece of power instance information included in the power management cluster under design, the reset controller instance information, the reset test controller instance information, connection information between the scan test controller and the reset controller instance, connection information between the power instance and the reset controller instance, and connection information between the reset controller instance and the reset test controller instance.

The hardware code logic storage 834 stores hardware code logic for generating hardware code based on the designed power management cluster information, the power instance information, and the register information. When the power instance is generated as hardware code, it may be manufactured as a power element. When the reset controller instance is generated as hardware code, it may be implemented as a reset controller. When the reset test controller instance is generated as hardware code, it may be implemented as a reset test controller. In addition, when each piece of connection information is generated as hardware code, the scan test controller and the reset controller may be connected, the reset controller and the reset test controller may be connected, and the reset controller and the power element may be connected.

### Power Management Cluster Processor 820

The power management cluster processor 820 includes: a power instance generator 821 that generates a new power instance based on the power component information; a reset controller instance generator 822 that generates a reset controller instance connected to a power instance; and a reset test controller instance generator 823 that generates a reset test controller instance connected to a reset controller instance.

The power instance generator 821 may be executed to generate a new power instance when a user adds any power component of the power component window 920 to the design window 940. The name of the new power instance may include the name of the power management cluster under design including the new power instance and the power component type information of the new power instance. The power instance generator 821 may automatically generate essential power instances without user input. For example, the cold reset control instance and the soft reset control instance may be included as essential in the root power manager.

The reset controller instance generator 822 generates the reset controller instance that is disposed upstream of the power instance and transmits a reset output to at least one target including the power instance. At least two reset controller instances may be designed to be connected. The reset controller instances may be set as the leading reset controller instance and the following reset controller instance. The reset controller instance generator 822 may automatically operate when the power instance is generated to generate the reset controller instance and set the connection information between the power instance and the reset controller instance without user input.

The leading reset controller instance includes: a synchronizer block connected to the functional clock of the target; a first test multiplexer block having a scan reset control signal (ltest_reset) and a reset input (RESET_IN) connected to respective input terminals and a scan test enable signal (ltest_en) connected to a selection terminal; a first OR operator block having an output of the first test multiplexer block and a scan reset deactivation signal (ltest_rstdisable) connected to input terminals and a synchronizer block connected to an output terminal; a second OR operator block having an output of the synchronizer block and a scan reset deactivation signal (ltest_rstdisable) connected to input terminals; and a second test multiplexer block having an output of the second OR operator block and reset test data (TEST_MODE_RESET) input to respective input terminals, a reset test mode signal (TEST_MODE) connected to a selection terminal, and a reset output (RESET_OUT) connected to the target.

The synchronizer block and the first test multiplexer block, the first OR operator block, the second OR operator block and the second test multiplexer block of the leading reset controller instance may each be generated as hardware code and implemented as the synchronizer 633, the first test multiplexer 631, the first OR operator 632, the second OR operator 634 and the second test multiplexer 635 of FIG. 6.

The following reset controller instance includes: a synchronizer block connected to the functional clock of the target; a first test multiplexer block in which both the selection terminal and one of the input terminals are fixed to zero level, and the reset input is connected to another input terminal; a first OR operator block having an output of the first test multiplexer block and a scan reset deactivation signal (ltest_rstdisable) connected to input terminals and a synchronizer block connected to an output terminal; a second OR operator block having an output of the synchronizer block and a scan reset deactivation signal (ltest_rstdisable) connected to input terminals; and a second test multiplexer block having an output of the second OR operator block and reset test data (TEST_MODE_RESET) input to respective input terminals, a reset test mode signal (TEST_MODE) connected to a selection terminal, and a reset output (RESET_OUT) connected to the target.

The synchronizer block and the first test multiplexer block, the first OR operator block, the second OR operator block and the second test multiplexer block of the following reset controller instance may each be generated as hardware code and implemented as the synchronizer 733, the first test multiplexer 731, the first OR operator 732, the second OR operator 734 and the second test multiplexer 735 of FIG. 7.

The reset test controller instance generator 823 may automatically operate when a reset controller instance is generated without a user input to generate a reset test controller instance, and may generate connection information between the reset controller instance and the reset test controller instance. The reset test controller instance may include the test mode TDR block and the test control TDR block. The test mode TDR block is set to provide the reset test mode signal (TEST_MODE) to the selection terminal of the second test multiplexer block of the reset controller instance, and the test control TDR block is set to provide the reset test data (TEST_MODE_RESET) to the second test multiplexer block of the reset controller instance. The reset test controller instance generator 823 may generate the test control TDR block configured with a flip-flop chain as many as the number of bits of the reset test data.

The reset test controller instance is a controller based on a built-in IEEE1687 standard, and the test mode TDR block and the test control TDR block may be designed to be set via the IJTAG interface, respectively.

### Hardware Code Processor 840

The hardware code processor 840 may include: a power hardware code generator 841 that generates hardware code corresponding to a functional module of a power element based on designed power instance information; a reset controller hardware code generator 842 that generates hardware code corresponding to a reset controller based on designed reset controller instance information; and a reset test controller hardware code generator 843 that generates hardware code corresponding to a reset test controller based on reset test controller instance information. By driving the hardware code processor 840, the power instance, the reset controller instance, and the reset test controller instance may be implemented as the power element, the reset controller, and the reset test controller of FIGS. 2 to 7, respectively.

The hardware code processor 840 may be executed when the GENRTL button of the command window 910 is selected. A user may select and execute the GENRTL button while the power diagram of the power management cluster under design is displayed in the design window 940, and may also execute the check button before executing the GENRTL button to verify in advance whether there is an error in the power diagram.

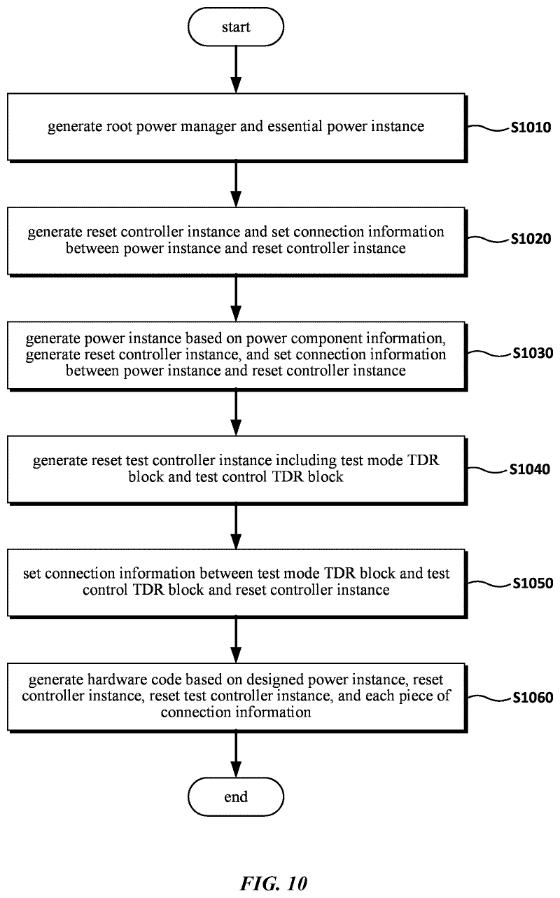

FIG. 10 is an operation flow diagram illustrating a power management cluster design method using a no-code approach according to an embodiment of the present disclosure. The power management cluster design method using the no-code approach according to an embodiment of the present disclosure may be executed by a processor of a computer system.

The computer system includes a component storage in which power component information, reset controller component information, and reset test controller component information are stored, and a hardware code logic storage in which hardware code logic for generating a designed power management cluster as hardware code is stored.

The processor generates a root power manager according to the manipulation of a user, and generates an essential power instance in the root power manager (S1010).

The processor generates a reset controller instance that is disposed upstream of the power instance and transmits a reset output to a target, and sets connection information between the power instance and the reset controller instance (S1020).

The processor generates a new power instance based on the power component information according to the manipulation of a user, generates a reset controller instance upstream of the new power instance, and sets connection information between the power instance and the reset controller instance (S1030).

The reset controller instance may be one of a leading reset controller instance or a following reset controller instance.

The leading reset controller instance includes: a synchronizer block connected to the functional clock of the target; a first test multiplexer block having a scan reset control signal (ltest_reset) and a reset input (RESET_IN) connected to respective input terminals and a scan test enable signal (ltest_en) connected to a selection terminal; a first OR operator block having an output of the first test multiplexer block and a scan reset deactivation signal (ltest_rstdisable) connected to input terminals and a synchronizer block connected to an output terminal; a second OR operator block having an output of the synchronizer block and a scan reset deactivation signal (ltest_rstdisable) connected to input terminals; and a second test multiplexer block having an output of the second OR operator block and reset test data (TEST_MODE_RESET) input to respective input terminals, a reset test mode signal (TEST_MODE) connected to a selection terminal, and a reset output (RESET_OUT) connected to the target.

The following reset controller instance includes: a synchronizer block connected to the functional clock of the target; a first test multiplexer block having a selection terminal and one input terminal fixed to zero level, respectively and a reset input connected to another input terminal; a first OR operator block having an output of the first test multiplexer block and a scan reset deactivation signal (ltest_rstdisable) connected to input terminals and a synchronizer block connected to an output terminal; a second OR operator block having an output of the synchronizer block and a scan reset deactivation signal (ltest_rstdisable) connected to input terminals; and a second test multiplexer block having an output of the second OR operator block and reset test data (TEST_MODE_RESET) input to respective input terminals, a reset test mode signal (TEST_MODE) connected to a selection terminal, and a reset output (RESET_OUT) connected to the target.

The processor generates a reset test controller instance for generating a reset test mode signal (TEST_MODE) and reset test data (TEST_MODE_RESET) in the test mode (S1040). The reset test controller instance includes a test mode TDR block and a test control TDR block. The test mode TDR block is set to output the reset test mode signal to the reset controller instance, and the test control TDR block is set to output the reset test data to the reset controller instance.

The processor sets connection information between the test mode TDR block and the test control TDR block and the reset controller instance (S1050). In other words, the test mode signal of the test mode TDR block is connected to the selection terminal of the second test multiplexer block, and the reset test data of the test control TDR block is connected to the input terminal of the second test multiplexer block.

The processor generates a hardware code of a power management cluster designed based on the power instance, the reset controller instance, the reset test controller instance, each piece of connection setting information, and the hardware code logic (S1060).

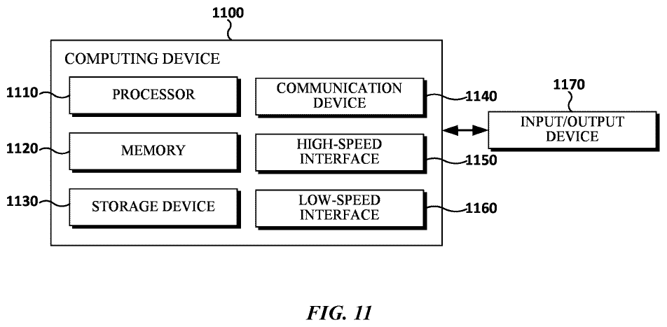

FIG. 11 illustrates an exemplary computing device 1100 for performing the method and/or embodiments described above. According to an embodiment, the computing device 1100 may be implemented using hardware and/or software configured to interact with a user. Herein, the computing device 1100 may include a laptop computer, a desktop computer, a workstation, a personal digital assistant, a server, a blade server, and a mainframe computer, which is not limited thereto. The components of the computing device 1100 and connection relationships and functions thereof are intended to be illustrative and not intended to limit the implementations of the present disclosure described and/or claimed herein.

The computing device 1100 includes a processor 1110, a memory 1120, a storage device 1130, a communication device 1140, a high-speed interface 1150 connected to the memory 1120 and a high-speed expansion port, and a low-speed interface 1160 connected to a low-speed bus and a low-speed storage device. Each of the components 1110, 1120, 1130, 1140, 1150 and 1160 may be interconnected using a variety of buses, mounted on the same main board, or mounted and connected in other suitable ways. The processor 1110 may be configured to process instructions of a computer program by performing basic arithmetic, logic, and input/output operations. For example, the processor 1110 may process instructions stored in the memory 1120 and the storage device 1130 and/or instructions executed within the computing device 1100 and display graphic information on an external input/output device 1170 such as a display device combined with the high-speed interface 1150.

The communication device 1140 may provide a configuration or a function for the input/output device 1170 and the computing device 1100 to communicate with each other through a network and provide a configuration or a function to support the input/output device 1170 and/or the computing device 1100 to communicate with another external apparatus. For example, a request or data generated by the processor of the external apparatus according to an arbitrary program code may be transmitted to the computing device 1100 through a network under the control of the communication device 1140. Conversely, a control signal or a command provided under the control of the processor 1110 of the computing device 1100 may be transmitted to another external device through the communication device 1140 and a network.

FIG. 11 illustrates that the computing device 1100 includes one processor 1110 and one memory 1120, but is not limited thereto, and the computing device 1100 may be implemented using a plurality of memories, a plurality of processors, and/or a plurality of buses. In addition, although FIG. 11 illustrates that one computing device 1100 is employed, but is not limited thereto, and a plurality of computing devices may interact with each other and perform operations required to execute the method described above.

The memory 1120 may store information in the computing device 1100. According to an embodiment, the memory 1120 may include a volatile memory unit or a plurality of memory units. Additionally or alternatively, the memory 1120 may be composed of a non-volatile memory unit or a plurality of memory units. In addition, the memory 1120 may be implemented using a different type of computer-readable medium, such as a magnetic disc or an optical disc. In addition, an operating system and at least one program code and/or instruction may be stored in the memory 1120.

The storage device 1130 may be one or more mass storage devices for storing data for the computing device 1100. For example, the storage device 1130 may be configured to include a hard disc; a magnetic disc such as a portable disc; an optical disc; a semiconductor memory device such as an erasable programmable read-only memory (EPROM), an electrically erasable PROM (EEPROM), and a flash memory; and a computer-readable medium including a CD-ROM or DVD-ROM disc; or the storage device 1130 may be configured to include the computer-readable medium. In addition, the computer program may be implemented tangibly in the computer-readable medium.

The high-speed interface 1150 and the low-speed interface 1160 may be used for interaction with the input/output device 1170. For example, an input device may include a camera including an audio sensor and/or an image sensor, a keyboard, a microphone, and a mouse; an output device may include a display, a speaker, and a haptic feedback device. In another example, the high-speed interface 1150 and the low-speed interface 1160 may be used for interfacing with a device in which a configuration or function for performing input and output operations is integrated into one entity, such as a touch screen.

According to an embodiment, the high-speed interface 1150 manages bandwidth-intensive operations for the computing device 1100, while the low-speed interface 1160 manages less bandwidth-intensive operations than the high-speed interface 1150, where the above functional assignment has been made merely for an illustrative purpose. According to an embodiment, the high-speed interface 1150 may be coupled to high-speed expansion ports capable of accommodating the memory 1120, the input/output device 1170, and various expansion cards (not shown). In addition, the low-speed interface 1160 may be coupled to the storage device 1130 and low-speed expansion ports. In addition, the low-speed expansion port, which may include various communication ports (for example, USB, Bluetooth, Ethernet, and wireless Ethernet), may be coupled to one or more input/output devices 1170, such as a keyboard, a pointing device, and a scanner, or a networking device, such as a router or a switch, through a network adaptor.

The computing device 1100 may be implemented in many different forms. For example, the computing device 1100 may be implemented as a standard server or a group of standard servers. Additionally or alternatively, the computing device 1100 may be implemented as part of a rack server system or may be implemented as a personal computer, such as a laptop computer. In this connection, components from the computing device 1100 may be combined with other components of an arbitrary mobile device (not shown). The computing device 1100 may include one or more other computing devices or may be configured to communicate with one or more computing devices.

FIG. 11 illustrates that the input/output device 1170 is not included in the computing device 1100, but is not limited thereto, and the input/output device 1170 may be configured to be integrated into the computing device 1100 to form a single device. In addition, FIG. 11 illustrates that the high-speed interface 1150 and/or the low-speed interface 1160 are illustrated as being configured separately from the processor 1110, but is not limited thereto, and the high-speed interface 1150 and/or the low-speed interface 1160 may be configured to be included in the processor 1110.

The method and/or various embodiments described above may be implemented in digital electronic circuitry, computer hardware, firmware, software, and/or a combination thereof. Various embodiments of the present disclosure may be executed by a data processing device, for example, one or more programmable processors and/or one or more computing devices; or implemented as a computer-readable medium and/or a computer program stored on a computer-readable medium. The computer program may be written in any form of programming language including a compiled language or an interpreted language and may be distributed in any form such as a stand-alone program, a module, or a subroutine. The computer program may be distributed via a plurality of computing devices connected through one computing device and the same network and/or a plurality of distributed computing devices connected through a plurality of different networks.

The method and/or various embodiments described above may be performed by one or more processors configured to execute one or more computer programs that process, store, and/or manage arbitrary functions by operating based on input data or generating output data. For example, the method and/or various embodiments of the present disclosure may be performed by a special-purpose logic circuit such as a Field Programmable Gate Array (FPGA) or an Application Specific Integrated Circuit (ASIC); an apparatus and/or a system for performing the method and/or various embodiments of the present disclosure may be implemented as a special-purpose logic circuit such as an FPGA or an ASIC.

The one or more processors executing the computer program may include a general-purpose or special-purpose microprocessor and/or one or more processors of an arbitrary type of digital computing device. The processor may receive instructions and/or data from each of the read-only memory and the random-access memory or may receive instructions and/or data from the read-only memory and the random-access memory. In an embodiment of the present disclosure, the components of a computing device performing the method and/or embodiments may include one or more processors for executing instructions; and one or more memories for storing instructions and/or data.

According to an embodiment, the computing device may send and receive data to and from one or more mass storage devices for storing data. For example, the computing device may receive data from a magnetic or optical disc and transmit data to the magnetic or optical disc. A computer-readable medium suitable for storing instructions and/or data related to a computer program may include any form of non-volatile memory including a semiconductor memory device such as an Erasable Programmable Read-Only Memory (EPROM), an Electrically Erasable PROM (EEPROM), and a flash memory device, without being limited thereto. For example, a computer-readable medium may include a magnetic disc such as an internal hard disc or a removable disc, a photomagnetic disk, a CD-ROM disc, and a DVD-ROM disc.

To provide interaction with a user, the computing device may include a display device (for example, a cathode ray tube (CRT) or a liquid crystal display (LCD)) for providing or displaying information to a user and a pointing device (for example, a keyboard, a mouse, or a trackball) through which the user may provide input and/or commands to the computing device by the user, without being limited thereto. In other words, the computing device may further include any other kind of device for providing interaction with the user. For example, the computing device may provide any form of sensory feedback to the user for interaction with the user, including visual feedback, auditory feedback, and/or tactile feedback. In response to the feedback, the user may provide input to the computing device through various gestures including a visual expression, voice, and motion.

In the present disclosure, various embodiments may be implemented in a computing device that includes a back-end component (for example, a data server), a middleware component (for example, an application server), and/or a front-end component. In this connection, the components may be interconnected by any form or any medium of digital data communication, such as a communication network. According to an embodiment, the communication network includes a wired network such as Ethernet, a wired home network (Power Line Communication), a telephone line communication device, and RS-serial communication; a wireless network such as a mobile communication network, a wireless LAN (WLAN), Wi-Fi, and Bluetooth; or a combination of the wired and wireless networks. For example, the communication network may include a local area network (LAN) and a wide area network (WAN).

A computing device based on the illustrative embodiments described herein may be implemented using hardware and/or software configured to interact with a user, including a user device, a user interface (UI) device, a user terminal, or a client device. For example, the computing device may include a portable computing device such as a laptop computer. Additionally or alternatively, the computing device may include a Personal Digital Assistants (PDA), a tablet PC, a game console, a wearable device, an Internet of Things (IOT) device, a virtual reality (VR) device, and an augmented reality (AR) device, but is not limited thereto. The computing device may further include other types of devices configured to interact with a user. In addition, the computing device may include a portable communication device (e.g., a mobile phone, a smartphone, or a wireless cellular phone) suitable for wireless communication over a network, such as a mobile communication network. The computing device may be configured to communicate wirelessly with a network server using wireless communication technologies and/or protocols such as Radio Frequency (RF), Microwave Frequency (MWF), and/or Infrared Ray Frequency (IRF).

Various embodiments of the present disclosure, including specific structural and functional details, are illustrative in nature. Accordingly, the embodiments of the present disclosure are not limited to those described above and may be implemented in various other forms. In addition, the terms used in the present disclosure are intended for describing some embodiments and should not be construed as limiting the embodiments. For example, singular words and the descriptions above may be construed to include plural forms unless the context dictates otherwise.

Unless defined otherwise, terms used in the present disclosure, including technical or scientific terms, may convey the same meaning understood generally by those skilled in the art to which the present disclosure belongs. Among the terms used in the present disclosure, commonly used terms, such as those defined in ordinary dictionaries, should be interpreted to convey the same meaning in the context of related technology.

The present disclosure has been described with reference to particular embodiments; however, various modifications and changes may be made without departing from the technical scope of the present disclosure that may be understood by those skilled in the art to which the present disclosure belongs. In addition, it should be understood that the modifications and changes fall within the technical scope of the appended claims.

### Detailed Description of Main Elements

810: screen window processor
811: command window processor
812: content window processor
813: design window processor
814: setting window processor
820: power management cluster processor
821: power instance generator
822: reset controller instance generator
823: reset test controller instance generator
830: data storage
831: component storage
832: content storage
833: power management cluster storage
834: hardware code logic storage
840: hardware code processor
841: power hardware code generator
842: reset controller hardware code generator
843: reset test controller hardware code generator

What is claimed is:

1. A system for designing a power management cluster using a no-code approach, the system comprising:
a memory configured to store at least one instruction;
a power component storage in which power component information, reset controller component information, and reset test controller component information configuring the power management cluster are stored;
a hardware code logic storage in which hardware code logic for generating the designed power management cluster as hardware code is stored; and
at least one processor configured to execute the at least one instruction stored in the memory,
wherein the at least one instruction comprises instructions for:
generating a power instance based on power component information;
generating a reset controller instance that is disposed upstream of the power instance and transmits a reset output to a target comprising the power instance;
setting first connection information between the target and the reset controller instance;
generating a reset test controller instance that comprises a test mode TDR block and a test control TDR block corresponding to the reset controller instance;
setting second connection information between the reset controller instance and the reset test controller instance; and
generating the hardware code based on the power instance, the reset controller instance, the first connection information, the reset test controller instance, the second connection information, and the hardware code logic.

2. The system for designing a power management cluster of claim 1, wherein the reset controller instance is one of a leading reset controller instance or a following reset controller instance.

3. The system for designing a power management cluster of claim 2, wherein the leading reset controller instance comprises:
a synchronizer block connected to a functional clock of the target;
a first test multiplexer block having two input terminals respectively connected to a scan reset control signal (ltest_reset) and a reset input (RESET_IN), and having a selection terminal connected to a scan test enable signal (ltest_en);
a first OR operator block having two input terminals respectively connected to an output of the first test multiplexer block and a scan reset deactivation signal (ltest_rstdisable), and having an output terminal connected to the synchronizer block;
a second OR operator block having two input terminals respectively connected to an output of the synchronizer block and the scan reset deactivation signal (ltest_rstdisable); and
a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

4. The system for designing a power management cluster of claim 2, wherein the following reset controller instance comprises:
a synchronizer block connected to a functional clock of the target;
a first test multiplexer block in which a selection terminal and one input terminal are fixed to a zero level, and a reset input is connected to another input terminal;
a first OR operator block having two input terminals respectively connected to an output of the first test multiplexer block and a scan reset deactivation signal (ltest_rstdisable), and having an output terminal connected to the synchronizer block;
a second OR operator block having two input terminals respectively connected to an output of the synchronizer block and the scan reset deactivation signal (ltest_rstdisable); and
a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

5. The system for designing a power management cluster of claim 1, wherein the reset test controller instance is implemented based on a built-in IEEE1687 standard.

6. The system for designing a power management cluster of claim 1, wherein:
the test mode TDR block is set to output a reset test mode signal (TEST_MODE) to the reset controller instance to activate or deactivate a test mode of the target; and
the test control TDR block is set to output reset test data (TEST_MODE_RESET) to the reset controller instance in the test mode of the target.

7. The system for designing a power management cluster of claim 6, wherein the test control TDR block comprises a plurality of flip-flop blocks corresponding to the number of bits of the reset test data.

8. The system for designing a power management cluster of claim 1, wherein the test mode TDR block and the test control TDR block are each set via an internal joint test action group (IJTAG) interface.

9. The system for designing a power management cluster of claim 1, wherein the power component is at least one of a reset component, a clock link component, a cold reset control component, a soft reset control component or a domain power manager (PMD) connection component.

10. A method for designing a power management cluster using a no-code approach, the method being performed by at least one processor in a computer system comprising: a power component storage in which power component information, reset controller component information, and reset test controller component information configuring the power management cluster are stored; and a hardware code logic storage in which hardware code logic for generating the designed power management cluster as hardware code is stored, wherein the method comprises:
generating a power instance based on power component information;
generating a reset controller instance that is disposed upstream of the power instance and transmits a reset output to a target comprising the power instance;
setting first connection information between the target and the reset controller instance;
generating a reset test controller instance that comprises a test mode TDR block and a test control TDR block corresponding to the reset controller instance;
setting second connection information between the reset controller instance and the reset test controller instance; and
generating the hardware code based on the power instance, the reset controller instance, the first connection information, the reset test controller instance, the second connection information, and the hardware code logic.

11. The method for designing a power management cluster of claim 10, wherein the reset controller instance is one of a leading reset controller instance or a following reset controller instance.

12. The method for designing a power management cluster of claim 11, wherein the leading reset controller instance comprises:
a synchronizer block connected to a functional clock of the target;
a first test multiplexer block having two input terminals respectively connected to a scan reset control signal (ltest_reset) and a reset input (RESET_IN), and having a selection terminal connected to a scan test enable signal (ltest_en);
a first OR operator block having two input terminals respectively connected to an output of the first test multiplexer block and a scan reset deactivation signal (ltest_rstdisable), and having an output terminal connected to the synchronizer block;
a second OR operator block having two input terminals respectively connected to an output of the synchronizer block and the scan reset deactivation signal (ltest_rstdisable); and
a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

13. The method for designing a power management cluster of claim 11, wherein the following reset controller instance comprises:
a synchronizer block connected to a functional clock of the target;
a first test multiplexer block in which a selection terminal and one input terminal are fixed to a zero level, and a reset input is connected to another input terminal;
a first OR operator block having two input terminals respectively connected to an output of the first test multiplexer block and a scan reset deactivation signal (ltest_rstdisable), and having an output terminal connected to the synchronizer block;
a second OR operator block having two input terminals respectively connected to an output of the synchronizer block and the scan reset deactivation signal (ltest_rstdisable); and
a second test multiplexer block having two input terminals respectively connected to an output of the second OR operator block and reset test data (TEST_MODE_RESET), a selection terminal connected to a reset test mode signal (TEST_MODE), and a reset output (RESET_OUT) connected to the target.

14. The method for designing a power management cluster of claim 10, wherein the reset test controller instance is implemented based on a built-in IEEE1687 standard.

15. The method for designing a power management cluster of claim 10, wherein:
the test mode TDR block is set to output a reset test mode signal (TEST_MODE) to the reset controller instance to activate or deactivate a test mode of the target; and
the test control TDR block is set to output reset test data (TEST_MODE_RESET) to the reset controller instance in the test mode of the target.

16. The method for designing a power management cluster of claim 15, wherein the test control TDR block comprises a plurality of flip-flop blocks corresponding to the number of bits of the reset test data.

17. The method for designing a power management cluster of claim 10, wherein the test mode TDR block and the test control TDR block are each set via an internal joint test action group (IJTAG) interface.

18. The method for designing a power management cluster of claim 10, wherein the power component is at least one of a reset component, a clock link component, a cold reset control component, a soft reset control component or a domain power manager (PMD) connection component.
